(19) United States
(12) Patent Application Publication
(10) Pub. No.: US 2008/0308914 A1
(43) Pub. Date: Dec. 18, 2008

(54) CHIP PACKAGE

(75) Inventors: Geng-Shin Shen, Tainan County (TW); David Wei Wang, Tainan County (TW)

Correspondence Address: J C PATENTS, INC., 4 VENTURE, SUITE 250, IRVINE, CA, 92618, US

(73) Assignees: CHIPMOS TECHNOLOGIES INC., Hsinchu (TW); CHIPMOS TECHNOLOGIES (BERMUDA) LTD., Hamilton (BM)

(21) Appl. No.: 12/198,517

(22) Filed: Aug. 26, 2008

Related U.S. Application Data
(63) Continuation-in-part of application No. 11/481,719, filed on Jul. 5, 2006.

(30) Foreign Application Priority Data
Mar. 17, 2006 (TW) 95109125

(51) Int. Cl. H01L 23/12

(52) U.S. Cl. 257/668; 257/E23.003

(57) ABSTRACT

A chip package including a circuit substrate having an opening, a first chip, first bonding wires, a component, a first adhesive layer and a molding compound is provided. The first chip has a first active surface and a first rear surface opposite to the first active surface, the first chip is flipped on and electrically connected with the circuit substrate. The first bonding wires are electrically connected with the circuit substrate and the first chip, and each first bonding wire passes through the opening. The component is disposed over the first rear surface. The first adhesive layer adhered between the first rear surface and the component includes a first B-staged adhesive layer adhered on the first rear surface and the component and a second B-staged adhesive layer adhered between the first B-staged adhesive layer and the component. The molding compound is disposed on the circuit substrate.

### CROSS-REFERENCE TO RELATED APPLICATION

This application is a continuation in part (CIP) application of application Ser. No. 11/481,719, filed on Jul. 5, 2006, which claims the priority benefit of Taiwan application serial No. 95109125, filed on Mar. 17, 2006. The entirety of each of the above-mentioned patent applications is hereby incorporated by reference herein and made a part of this specification.

### BACKGROUND OF THE INVENTION

1. Field of the Invention

The present invention generally relates to a chip package. More particularly, the present invention relates to a chip package with enhanced reliability and reduced production cost.

2. Description of Related Art

In recent years, chip package having a plurality of stacked chips is gradually developed. In most chip packages, the chips are stacked over and electrically connected to a carrier (e.g. a printed circuit board or a lead-frame) through bonding wires or bumps, such as gold bumps, copper bumps, polymer bump, or solder bumps. Generally, each of the chips stacked over the carrier is adhered with the other chips or the carrier by an adhesive (e.g. tapes or adhesion glue). Specifically, the tape with proper size and stickiness is attached on the chips or on the carrier when the tapes are used in the die-bonding process or chip-stacking process; and the adhesion glue is dispensed on the chips or on the carrier and is then cured when the adhesion glue is used in the die-bonding process or chip-stacking process. Since the tape must be cut into proper size in advance when using for performing the die-bonding process or chip-stacking process, the use of the tape is unfavorable to mass production. Additionally, the reliability of the chip package is affected because the thickness of the adhesion glue is difficult to control. Therefore, a solution is required to enhance the reliability and reduce the production cost of chip packages.

### SUMMARY OF THE INVENTION

The present invention is to provide a chip package having enhanced reliability and reduced production cost.

As embodied and broadly described herein, the present invention provides a chip package including a circuit substrate having an opening, a first chip, a plurality of first bonding wires, a component, a first adhesive layer and a molding compound. The first chip has a first active surface and a first rear surface opposite to the first active surface, the first chip is flipped on and electrically connected with the circuit substrate. The first bonding wires are electrically connected with the circuit substrate and the first chip, and each of the first bonding wires passes through the opening of the circuit substrate. The component is disposed over the first rear surface of the first chip. The first adhesive layer adhered between the first rear surface of the first chip and the component includes a first B-staged adhesive layer adhered on the first rear surface of the first chip and a second B-staged adhesive layer adhered between the first B-staged adhesive layer and the component. The molding compound is disposed on the circuit substrate to cover the first chip, the component, the first adhesive layer and the first bonding wires.

According to an embodiment of the present invention, the opening is a though hole or a notch.

According to an embodiment of the present invention, the component is a second chip having a second rear surface and a second active surface opposite to the second rear surface, the second rear surface of the second chip is adhered with the first rear surface of the first chip through the first adhesive layer.

According to an embodiment of the present invention, the chip package further comprises a plurality of second bonding wires electrically connected with the second chip and the circuit substrate.

According to an embodiment of the present invention, the component is a heat sink.

According to an embodiment of the present invention, the bonding wires comprise gold wires.

According to an embodiment of the present invention, the chip package further comprises a second adhesive layer adhered between the first active surface of the first chip and the circuit substrate.

According to an embodiment of the present invention, the second adhesive layer comprises a third B-staged adhesive layer adhered on the first active surface of the first chip and a fourth B-staged adhesive layer adhered between the third B-staged adhesive layer and the circuit substrate.

According to an embodiment of the present invention, a glass transition temperature of the third B-staged adhesive layer is substantially the same with a glass transition temperature of the fourth B-staged adhesive layer.

According to an embodiment of the present invention, a glass transition temperature of the third B-staged adhesive layer is different from a glass transition temperature of the fourth B-staged adhesive layer.

According to an embodiment of the present invention, a glass transition temperature of the first B-staged adhesive layer is substantially the same with a glass transition temperature of the second B-staged adhesive layer.

According to an embodiment of the present invention, a glass transition temperature of the first B-staged adhesive layer is different from a glass transition temperature of the second B-staged adhesive layer.

Since the first adhesive layer utilized in the present invention includes a first B-staged adhesive layer and a second B-staged adhesive layer, the thickness of the first adhesive layer is easily controlled. Additionally, the first adhesive layer is favorable to mass production, since the first adhesive layer can be formed over the rear surface of a wafer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing a chip package according to the first embodiment of the present invention.

FIG. 2 is a schematic cross-sectional view showing a chip package according to the second embodiment of the present invention.

FIG. 3 and FIG. 4 are schematic cross-sectional views showing chip packages according to the third embodiment of the present invention.

FIG. 5A and FIG. 5B are top views showing the circuit substrates according to the different embodiments of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

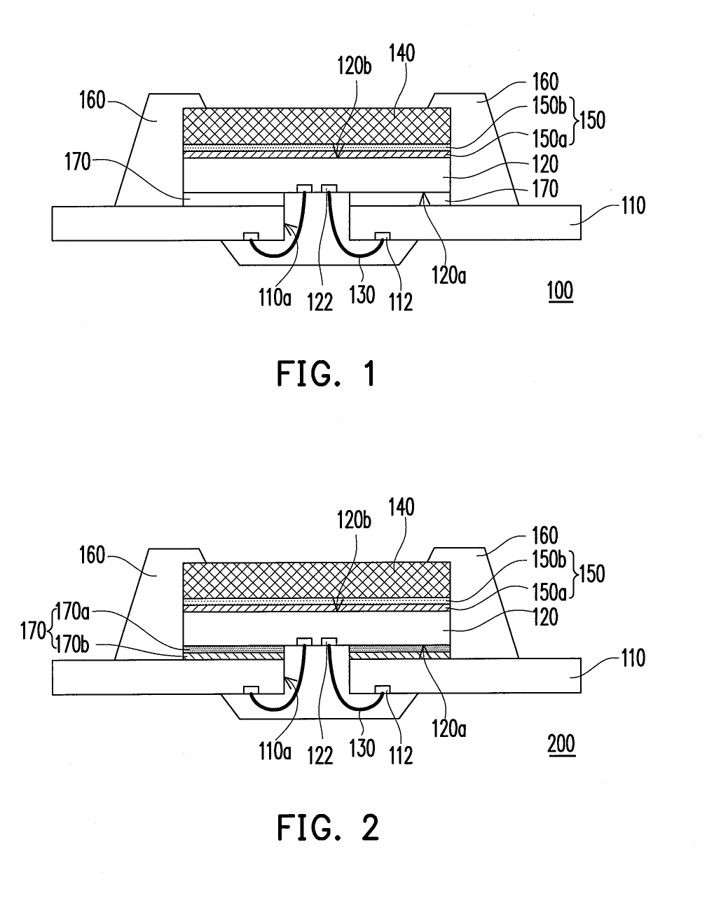

FIG. 1 is a schematic cross-sectional view showing a chip package according to the first embodiment of the present invention. Referring to FIG. 1, the chip package 100 of the present invention includes a circuit substrate 110 having an opening 110a, a first chip 120, a plurality of first bonding wires 130, a component 140, a first adhesive layer 150 and a molding compound 160. The first chip 120 has a first active surface 120a and a first rear surface 120b opposite to the first active surface 120a, the first chip 120 is flipped on and electrically connected with the circuit substrate 110. The first bonding wires 130 are electrically connected with the circuit substrate 110 and the first chip 120, and each of the first bonding wires 130 passes through the opening 110a of the circuit substrate 110. The component 140 is disposed over the first rear surface 120b of the first chip 120. The first adhesive layer 150 adhered between the first rear surface 120b of the first chip 120 and the component 140 includes a first B-staged adhesive layer 150a adhered on the first rear surface 120b of the first chip 120 and a second B-staged adhesive layer 150b adhered between the first B-staged adhesive layer 150a and the component 140. The molding compound 160 is disposed on the circuit substrate 110 to cover the first chip 120, the component 140, the first adhesive layer 150 and the first bonding wires 130.

For example, the circuit substrate 110 may be a circuit board, such as FR-4 substrate, FR-5 substrate, BT substrate, or the like.

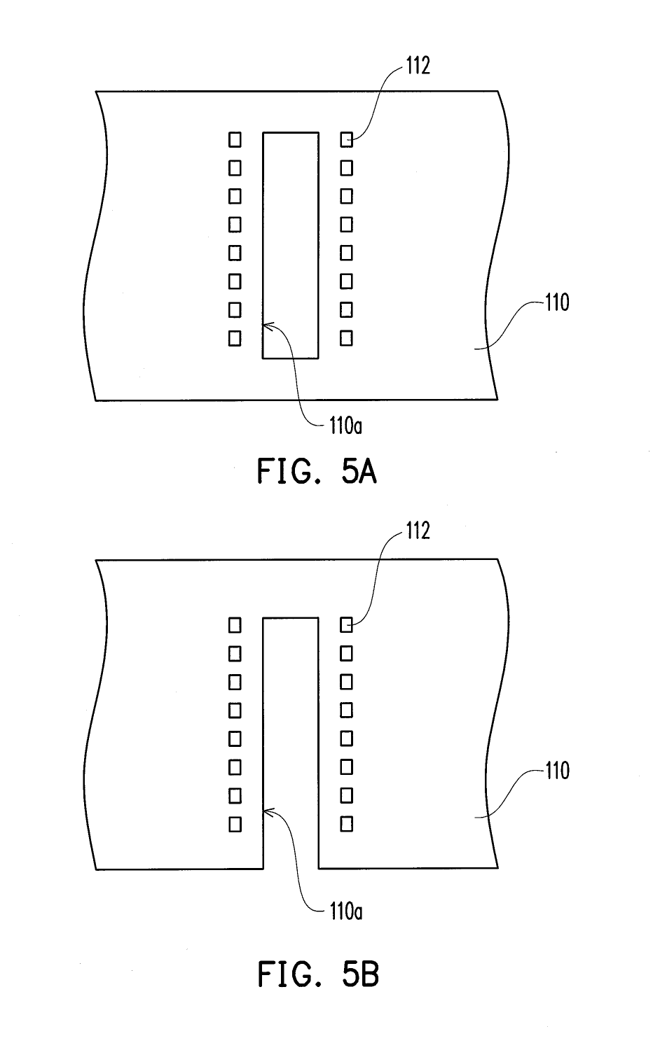

As shown in FIG. 1, the circuit substrate 110 has a plurality of first connecting pads 112 disposed on a surface of the circuit substrate 110, while the first chip 120 has a plurality of first bonding pads 122. The first connecting pads 112 are disposed around the opening 110a of the circuit substrate 110, and the first bonding pads 122 are exposed by the opening 110a of the circuit substrate 110. The first connecting pads 112 are electrically connected to the first bonding pads 122 through the first bonding wires 130. In the present embodiment, the bonding wires 130 are gold wires formed by wire bonding process. It is noted that the opening 110a of the circuit substrate 110 may be a though hole (shown in FIG. 5A) or a notch (shown in FIG. 5B). However, the opening 110a of the circuit substrate 110 can be of any suitable shape.

In the present embodiment, the component 140 is a heat sink. In order to enhance the heat dissipation performance, the component (heat sink) 140 may be partially encapsulated by the molding compound 160. In other words, a portion of the surface of the component (heat sink) 140 is exposed. In another embodiment of the present invention, the component (heat sink) 140 may be covered completely by the molding compound 160.

As shown in FIG. 1, the molding compound 160 fills into the opening 110a of the circuit substrate 110 and encapsulates the bonding wires 130 so as to prevent the bonding wires 130 from being damaged.

In the present embodiment, the first adhesive layer 150 is formed on the first rear surface 120b of the first chip 120 in advance. Specifically, a wafer having a plurality of first chip 120 arranged in an array is first provided. Then, a first two-stage adhesive layer is formed over the first rear surface 120b of the first chip 120 and is partially cured by heating or UV irradiation to form the first B-staged adhesive layer 150a. Afterward, a second two-stage adhesive layer is formed over the first B-staged adhesive layer 150a. Ultimately, the second two-stage adhesive layer is partially cured by heating or UV irradiation to form the second B-staged adhesive layer 150b. At this time, the first B-staged adhesive layer 150a and the second B-staged adhesive layer 150b are formed on the rear surface of the wafer. When the wafer is cut, a plurality of first chip 120 having the first adhesive layer 150 on the first rear surface 120b thereof is obtained. Therefore, the first adhesive layer 150 including the first B-staged adhesive layer 150a and the second B-staged adhesive layer 150b is favorable to mass production. Additionally, the first B-staged adhesive layer 150a and the second B-staged adhesive layer 150b may be formed by spin-coating, printing, or other suitable processes.

After the second B-staged adhesive layer 150b is partially cured, the first B-staged adhesive layer 150a may be further cured and has greater mechanical strength to maintain the gap between the first chip 120 and the component 140. At this time, the first B-staged adhesive layer 150a may be partially cures or fully cured to provide sufficient support, and the second B-staged adhesive layer 150b may be soft and sticky.

In the present embodiment, the first B-staged adhesive layer 150a and the second B-staged adhesive layer 150b are fully cured after the component 140 being attached to the first chip 120 or being encapsulated by the molding compound 160. The first B-staged adhesive layer 150a and the second B-staged adhesive layer 150b can be obtained from 8008 or 8008HT of ABLESTIK, and the glass transition temperature of which is between about 80° C. and about 300° C. Additionally, the first B-staged adhesive layer 150a and the second B-staged adhesive layer 150b can also be obtained from 6200, 6201 or 6202C of ABLESTIK or obtained from SA-200-6, SA-200-10 provided by HITACHI Chemical CO., Ltd., and the glass transition temperature of which is between about −40° C. and about 150° C. The glass transition temperature of the first B-staged adhesive layer 150a is greater than, substantially the same with, or smaller than the glass transition temperature of the second B-staged adhesive layer 150b. Additionally, some conductive particles (e.g. silver particles, copper particles, gold particles) are doped in the first B-staged adhesive layer 150a and the second B-staged adhesive layer 150b, for example.

As shown in FIG. 1, the chip package may further includes a second adhesive layer 170 adhered between the first active surface 120a of the first chip 120 and the circuit substrate 110. In other words, the first chip 120 is bonded onto the circuit substrate 110 by the second adhesive layer 170.

FIG. 2 is a schematic cross-sectional view showing a chip package according to the second embodiment of the present invention. Referring to FIG. 1 and FIG. 2, the chip package 200 of the present embodiment is similar with the chip package 100 shown in FIG. 1 except that the second adhesive layer 170 of the chip package 200 includes a third B-staged adhesive layer 170a adhered on the first active surface 120a of the first chip 120 and a fourth B-staged adhesive layer 170b adhered between the third B-staged adhesive layer 170a and the circuit substrate 110. It is noted that the third B-staged adhesive layer 170a and the fourth B-staged adhesive layer 170b may be formed on the first active surface 120a of the first chip 120 or on the circuit substrate 110 by spin-coating, printing, or other suitable processes.

In the present embodiment, the third B-staged adhesive layer 170a and the fourth B-staged adhesive layer 170b are fully cured after the first chip 120 being attached to the circuit substrate 110 or being encapsulated by the molding compound 160. The third B-staged adhesive layer 170a and the fourth B-staged adhesive layer 170b can be obtained from 8008 or 8008HT of ABLESTIK, and the glass transition temperature of which is between about 80° C. and about 300° C. Additionally, the third B-staged adhesive layer 170a and the fourth B-staged adhesive layer 170b can also be obtained from 6200, 6201 or 6202C of ABLESTIK or obtained from SA-200-6, SA-200-10 provided by HITACHI Chemical CO., Ltd., and the glass transition temperature of which is between about −40° C. and about 150° C. The glass transition temperature of the third B-staged adhesive layer 170a is greater than, substantially the same with, or smaller than the glass transition temperature of the fourth B-staged adhesive layer 170b. Additionally, some conductive particles (e.g. silver particles, copper particles, gold particles) are doped in the third B-staged adhesive layer 170a and the fourth B-staged adhesive layer 170b, for example.

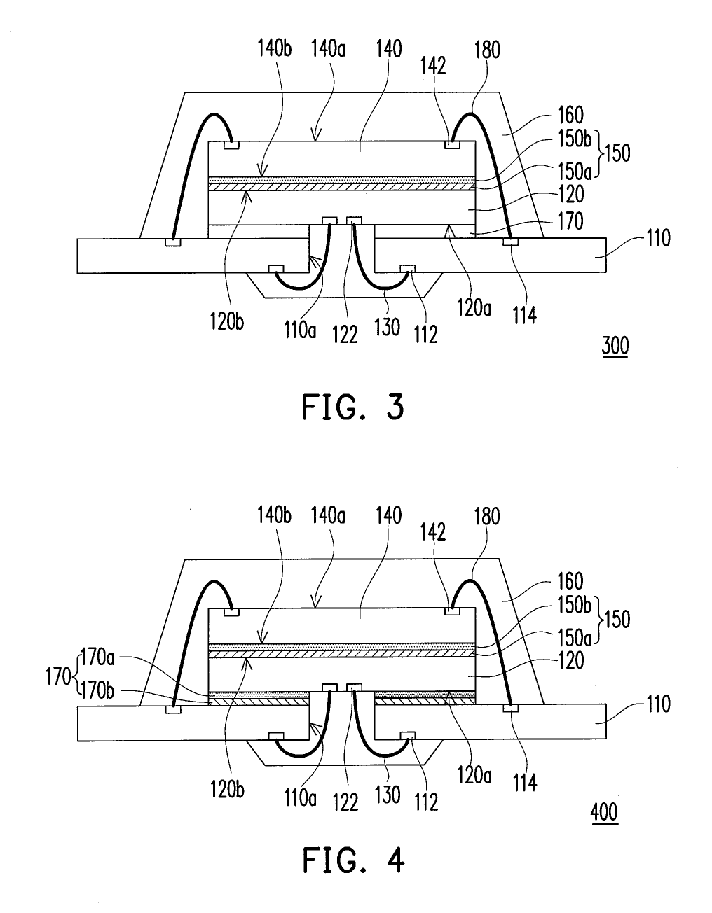

FIG. 3 and FIG. 4 are schematic cross-sectional views showing chip packages according to the third embodiment of the present invention. Referring to FIG. 3, the chip package 300 of the present embodiment is similar with the chip package 100 shown in FIG. 1 except that the component 140 is a second chip. Additionally, referring to FIG. 4, the chip package 400 of the present embodiment is similar with the chip package 200 shown in FIG. 2 except that the component 140 is a second chip.

As shown in FIG. 3 and FIG. 4, the circuit substrate 110 has a plurality of first connecting pads 112 and a plurality of second connecting pads 114, wherein the first connecting pads 112 are disposed on a surface of the circuit substrate 110 and the second connecting pads 114 are disposed on another surface of the circuit substrate 110. The second chip 140 has a second rear surface 140b and a second active surface 140a opposite to the second rear surface 140b. The second rear surface 140b of the second chip 140 is adhered with the first rear surface 120b of the first chip 120 through the first adhesive layer 150. The second chip 140 further has a plurality of second bonding pads 142 disposed on the second active surface 140a and the chip package 300 further includes a plurality of second bonding wires 180 electrically connected with the second bonding pads 142 of the second chip 140 and the second connecting pads 114 of the circuit substrate. It is noted that the component 140 may also be a passive device, such as a capacitor, a resistor, or an inductor.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package, comprising:
a circuit substrate having an opening;
a first chip having a first active surface and a first rear surface opposite to the first active surface, wherein the first chip is flipped on and electrically connected with the circuit substrate;
a plurality of first bonding wires electrically connected with the circuit substrate and the first chip, wherein each of the first bonding wires passes through the opening of the circuit substrate;
a component disposed over the first rear surface of the first chip; and
a first adhesive layer adhered between the first rear surface of the first chip and the component, wherein the first adhesive layer comprises:
a first B-staged adhesive layer adhered on the first rear surface of the first chip; and
a second B-staged adhesive layer adhered between the first B-staged adhesive layer and the component; and
a molding compound disposed on the circuit substrate to cover the first chip, the component, the first adhesive layer and the first bonding wires.

2. The chip package in accordance with claim 1, wherein the opening is a though hole or a notch.

3. The chip package in accordance with claim 1, wherein the component is a second chip having a second rear surface and a second active surface opposite to the second rear surface, the second rear surface of the second chip is adhered with the first rear surface of the first chip through the first adhesive layer.

4. The chip package in accordance with claim 3, further comprising a plurality of second bonding wires electrically connected with the second chip and the circuit substrate.

5. The chip package in accordance with claim 1, wherein the component is a heat sink.

6. The chip package in accordance with claim 1, wherein the bonding wires comprise gold wires.

7. The chip package in accordance with claim 1, further comprising a second adhesive layer adhered between the first active surface of the first chip and the circuit substrate.

8. The chip package in accordance with claim 7, wherein the second adhesive layer comprises:
a third B-staged adhesive layer adhered on the first active surface of the first chip; and
a fourth B-staged adhesive layer adhered between the third B-staged adhesive layer and the circuit substrate.

9. The chip package according to claim 8, wherein a glass transition temperature of the third B-staged adhesive layer is substantially the same with a glass transition temperature of the fourth B-staged adhesive layer.

10. The chip package according to claim 8, wherein a glass transition temperature of the third B-staged adhesive layer is different from a glass transition temperature of the fourth B-staged adhesive layer.

11. The chip package according to claim 1, wherein a glass transition temperature of the first B-staged adhesive layer is substantially the same with a glass transition temperature of the second B-staged adhesive layer.

12. The chip package according to claim 1, wherein a glass transition temperature of the first B-staged adhesive layer is different from a glass transition temperature of the second B-staged adhesive layer.
